(19) United States
(12) Patent Application Publication
(10) Pub. No.: US 2026/0177474 A1
(43) Pub. Date: Jun. 25, 2026

(54) MICRO-ELECTRO-MECHANICAL SYSTEM-BASED MATERIAL CORROSION ELECTROCHEMICAL MEASUREMENT SENSOR, PREPARATION METHOD THEREFOR, AND MATERIAL CORROSION ELECTROCHEMICAL MEASUREMENT EQUIPMENT

(71) Applicant: University of Science and Technology Beijing, Beijing (CN)

(72) Inventors: Xiaojia YANG, Beijing (CN); Qing LI, Beijing (CN); Renzheng ZHU, Beijing (CN); Xinyu WANG, Beijing (CN); Da WEI, Beijing (CN)

(73) Assignee: University of Science and Technology Beijing, Beijing (CN)

(21) Appl. No.: 19/386,033

(22) Filed: Nov. 11, 2025

(30) Foreign Application Priority Data
Dec. 19, 2024 (CN) 202411875685.4

(51) Int. Cl. G01N 17/02; B81C 1/00; G01N 17/04

(52) U.S. Cl. CPC G01N 17/02; B81C 1/00373; G01N 17/04

(57) ABSTRACT

Provided are a MEMS-based material corrosion electrochemical measurement sensor, a preparation method therefor, and material corrosion electrochemical measurement equipment. The sensor includes a working electrode-auxiliary electrode module including a first silicon substrate, a working electrode and an auxiliary electrode, where the first silicon substrate is provided with a recess portion, and the working electrode, the auxiliary electrode and the recess portion form an accommodation space; and a reference electrode module including a second silicon substrate and a reference electrode, where the reference electrode is disposed on one side of the second silicon substrate and forms a protruding portion, and the second silicon substrate is provided with a through hole. The protruding portion is disposed in the accommodation space, and the first silicon substrate is fixedly connected to the second silicon substrate.

### CROSS-REFERENCE TO RELATED APPLICATION

This patent application claims the benefit and priority of Chinese Patent Application No. 202411875685.4 filed with the China National Intellectual Property Administration on Dec. 19, 2024, the disclosure of which is incorporated by reference herein in its entirety as part of the present application.

### TECHNICAL FIELD

The present disclosure relates to the field of material corrosion sensors, and in particular to a MEMS-based material corrosion electrochemical measurement sensor, a preparation method therefor, and material corrosion electrochemical measurement equipment.

### BACKGROUND

The corrosion of materials in a natural environment is highly complex, and it is difficult to simulate accurately in a laboratory due to many influencing factors. Therefore, the actual corrosion data can only be obtained through long-term and continuous field tests and observations at field test sites. The high-throughput corrosion data collection and analytical mining for material environmental corrosion failure have long been a forefront and hotspot topic. The related work has a history of hundreds of years, and various sensors have been successively developed, including electrochemical resistance, inductive, galvanic couple, and alternating current impedance sensors, and related data accumulation and mining analysis have also been developed. The corresponding sensor technologies are mainly structural and solid sensors, and the application of such sensors in the field is limited. Therefore, to deploy material sensors on a large scale and obtain material corrosion data, it is necessary to develop the device-level material corrosion sensor with smaller size, lower cost and lower power consumption.

A Micro-Electro-Mechanical System (MEMS) material corrosion chip and sensor is an intelligent Micro-Electro-Mechanical sensor system capable of monitoring an environmental corrosion rate of the material, and processing and analyzing the environmental corrosion data artificially and intelligently. The sensor system has a MEMS material intelligent corrosion chip and an embedded Application Specific Integrated Circuit (ASIC) data processing chip. Compared with a conventional sensor, the sensor system has the characteristics of small volume, light weight, low cost, high reliability, suitability for mass production, easy integration and intelligent implementation. In recent years, the MEMS sensor and artificial intelligence data mining technology have developed rapidly, but there is no MEMS and corresponding corrosion chip development technology for material service failure evaluation. The conventional sensor has the characteristics of large volume, high power consumption, poor stability and low response sensitivity, which seriously hinders large-scale application of the material corrosion sensor and the development of material corrosion genetic engineering technology. In the field of material corrosion sensors, the realization of the chip-level material corrosion sensors, which can reduce monitoring cost and improve the measurement accuracy has remained a persistent challenge in the field of corrosion, and is also the international academic frontier and the focus of technical competition in the field of material corrosion genetic engineering. The key of the chip-level material corrosion sensors lies in developing the MEMS material corrosion chip and sensor to achieve in-situ, real-time and high-throughput online collection and mining analysis of corrosion data in the process of material service failure evaluation.

### SUMMARY

An objective of the present disclosure is to provide a MEMS-based material corrosion electrochemical measurement sensor, a preparation method therefor, and material corrosion electrochemical measurement equipment to solve the foregoing problems.

To achieve the objective, the present disclosure employs the technical solution as follows.

A MEMS-based material corrosion electrochemical measurement sensor includes:
a working electrode-auxiliary electrode module, including a first silicon substrate, a working electrode and an auxiliary electrode, where the first silicon substrate is provided with a recess portion, the working electrode is disposed on one side of an inner wall of the recess portion and a bottom of the recess portion, the auxiliary electrode is disposed on an opposite other side of the inner wall of the recess portion and the bottom of the recess portion, and the working electrode, the auxiliary electrode and the recess portion form an accommodation space; and
a reference electrode module, including a second silicon substrate and a reference electrode, where the reference electrode is disposed on one side of the second silicon substrate and forms a protruding portion, and the second silicon substrate is provided with a through hole in a thickness direction thereof;
where the protruding portion is disposed within the accommodation space, the working electrode, the auxiliary electrode and the reference electrode are not connected with one another, and the first silicon substrate is fixedly connected to the second silicon substrate; and
a spacing between the working electrode and the reference electrode is 1000-2000 μm (which may be 1000 μm, 1100 μm, 1200 μm, 1300 μm, 1400 μm, 1500 μm, 1600 μm, 1700 μm, 1800 μm, 1900 μm, 2000 μm, or any value between 1000-2000 μm), and a spacing between the working electrode and the auxiliary electrode is 1000-5000 μm (which may be 1000 μm, 1500 μm, 2000 μm, 2500 μm, 3000 μm, 3500 μm, 4000 μm, 4500 μm, 5000 μm, or any value between 1000-5000 μm).

A connected corrosion electrochemical three-electrode system should comply with measurement rules of corrosion electrochemistry. That is, an arrangement sequence of the working electrode, the reference electrode and the auxiliary electrode is satisfied as follows: the working electrode, the reference electrode and the auxiliary electrode, the working electrode and the reference electrode should be as close as possible to reduce ohmic resistance in the corrosion electrochemical measurement.

Preferably, a cross section of each of the working electrode and the auxiliary electrode is L-shaped.

Preferably, each of the working electrode, the auxiliary electrode and the reference electrode is made of a target metal material to be tested.

Preferably, a pair of the accommodation space and the protruding portion includes a plurality of pairs of accommodation spaces and protruding portions.

The present disclosure further provides a preparation method for the MEMS-based material corrosion electrochemical measurement sensor, including:
coating first semiconductor photoresist on one side of the first silicon substrate and carrying out first soft baking, carrying out exposure, development and dissolution by means of an electrolytic tank mask under corresponding ultraviolet light to form an exposed substrate region, and etching the exposed substrate region by ion etching to obtain the recess portion;
removing residual first semiconductor photoresist, coating second semiconductor photoresist on one side, with the recess portion, of the first silicon substrate and carrying out second soft baking, and carrying out exposure, development and dissolution by means of a working electrode mask under corresponding ultraviolet light to form a working electrode pattern, and forming a working electrode layer by disposing the target metal material to be tested on a position of the working electrode pattern by using a sputtering or electroplating method;
removing residual second semiconductor photoresist and a residual metal material to obtain the working electrode;
coating third semiconductor photoresist on one side, with the recess portion, of the first silicon substrate and carrying out third soft baking, and carrying out exposure, development and dissolution by means of an auxiliary electrode mask under corresponding ultraviolet light to form an auxiliary electrode pattern; forming an auxiliary electrode layer by disposing the target metal material to be tested on a position of the auxiliary electrode pattern by using the sputtering or electroplating method;
removing residual third semiconductor photoresist and a residual metal material to obtain the auxiliary electrode, thereby obtaining the working electrode-auxiliary electrode module;
disposing a reference electrode layer on a surface of one side of the second silicon substrate by using the sputtering or electroplating method, then coating fourth semiconductor photoresist and carrying out fourth soft baking, and carrying out exposure, development and dissolution by means of a reference electrode mask under corresponding ultraviolet light to form a reference electrode pattern, etching at a position of the reference electrode pattern by ion etching, and removing residual fourth semiconductor photoresist and a residual metal material to obtain the reference electrode;
coating fifth semiconductor photoresist on one side, away from the reference electrode, of the second silicon substrate and carrying out fifth soft baking, and carrying out exposure, development and dissolution by means of a through hole mask under corresponding ultraviolet light to form a through hole pattern, and etching at a position of the through hole pattern by the ion etching to obtain the through hole, thereby obtaining the reference electrode module; and
carrying out silicon-silicon bonding on the working electrode-auxiliary electrode module and the reference electrode module to obtain the MEMS-based material corrosion electrochemical measurement sensor.

Preferably, the first silicon substrate and the second silicon substrate are cleaned before use.

Preferably, temperatures for the first soft baking, the second soft baking, the third soft baking, the fourth soft baking and the fifth baking are independently 90° C.-110° C. respectively.

Preferably, prior to the silicon-silicon bonding, the first silicon substrate and the second silicon substrate are subjected to surface cleaning; and
the silicon-silicon bonding employs a heating-annealing treatment.

The present disclosure further provides material corrosion electrochemical measurement equipment, including the MEMS-based material corrosion electrochemical measurement sensor.

Preferably, the material corrosion electrochemical measurement equipment further includes a base lead frame,
where the working electrode, the auxiliary electrode and the reference electrode are electrically connected to the base lead frame.

Compared with the prior art, the present disclosure has beneficial effects as follows.

According to the MEMS-based material corrosion electrochemical measurement sensor provided by the present disclosure, the working electrode-auxiliary electrode module and the reference electrode module are combined, and bonded to form a three-electrode system for material corrosion electrochemical measurement. The sensor has the characteristics of small volume and low cost, is mature in preparation method, convenient for large-scale integration and batch fabrication, satisfying the requirements for online corrosion electrochemical monitoring of components with various specifications and materials. A width of an electrolytic tank (recess portion) should be greater than a width of the reference electrode to ensure that the reference electrode can be smoothly placed in a groove of the electrolytic tank. The quantity, size and position of the electrolytic tank can be adjusted according to actual needs, and the number of three-electrode systems may also be adjusted according to actual needs. The working electrode, the reference electrode and the auxiliary electrode can be replaced according to actual needs for material corrosion electrochemical measurement.

### BRIEF DESCRIPTION OF THE DRAWINGS

To describe the technical solution of embodiments of the present disclosure more clearly, the accompanying drawings used for the description of the embodiments of the present disclosure are briefly introduced below. It should be understood that the following accompanying drawings only show some embodiments of the present disclosure, and therefore should not be regarded as limiting the scope of the present disclosure.

FIG. 1 is a diagram of a preparation process of a working electrode-auxiliary electrode module according to an embodiment;

FIG. 2 is a diagram of a preparation process of a reference electrode module according to an embodiment;

FIG. 3 is a diagram of a bonding of a MEMS-based material corrosion electrochemical measurement sensor according to an embodiment;

FIG. 4 is a diagram of a base lead frame according to an embodiment;

FIG. 5 is a top view of material corrosion electrochemical measurement equipment according to an embodiment;

FIG. 6 is a perspective view of material corrosion electrochemical measurement equipment according to an embodiment;

FIG. 7 is a diagram showing a result of an open-circuit potential test of a sensor obtained according to an embodiment;

FIG. 8 is a diagram showing a result of an electrochemical alternating current impedance test of a sensor obtained according to an embodiment;

FIG. 9 is a diagram showing a result of a weak polarization test of a sensor obtained according to an embodiment;

FIG. 10 is a diagram showing a result of an electrochemical alternating current impedance test a sensor obtained according to Comparative Example 1;

FIG. 11 is a diagram showing a result of an electrochemical alternating current impedance test of a sensor obtained according to Comparative Example 2.

### REFERENCE NUMERALS

1—first silicon substrate; 2—second silicon substrate; 3—working electrode; 4—auxiliary electrode; 5—reference electrode; 6—electrolytic tank; 7—base lead frame; 8—bonding wire; 9—bonding pad; 10—through hole.

### DETAILED DESCRIPTION OF THE EMBODIMENTS

Implementations of the present disclosure are described in detail below with reference to specific embodiments, but those skilled in the art should understand that the following embodiments are only used to illustrate the present disclosure and should not be regarded as limiting the scope of the present disclosure. Unless otherwise specified in the embodiments, the procedures are carried out in standard conditions or according to the instructions of the manufacturers. All reagents and instruments used without specifying the manufacturers are conventional products that are commercially available.

### Embodiment

This embodiment provides a MEMS-based material corrosion electrochemical measurement sensor, with a preparation process as follows.

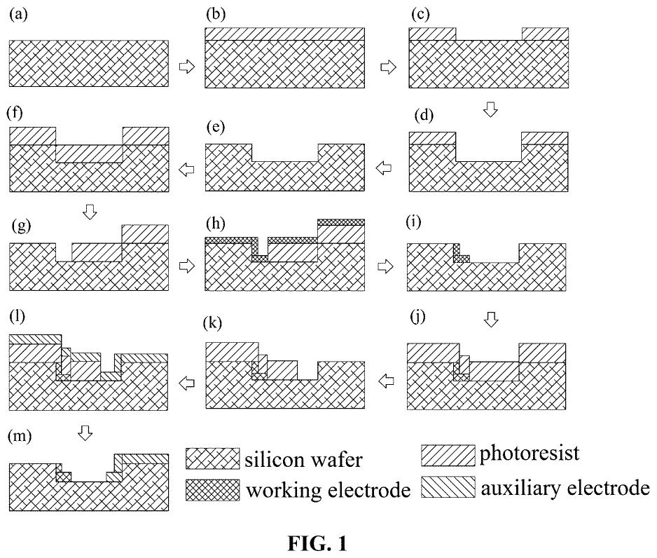

1. As shown in FIG. 1, a preparation process of an auxiliary electrode and a working electrode is specifically as follows.

1.1. A silicon wafer with a diameter of 100 mm and a thickness of 525 μm is used as a first substrate silicon wafer. A surface of the first substrate silicon wafer is cleaned with deionized water firstly. Afterwards, a cleaning solution composed of 25% hydrogen peroxide, 25% ammonia water and pure water in a volume ratio of 1:1:20 is used to clean the silicon wafer, where the cleaning lasts for about 270 s. Then, a cleaning solution composed of 30% hydrochloric acid, 25% hydrogen peroxide and pure water in a volume ratio of 1:1:20 is used to continually clean the silicon wafer for 250 s. Afterwards, the silicon wafer is washed with a large amount of deionized water, and dried by high-speed spin-drying equipment, where the spin-drying process lasts for 290 s to 310 s.

1.2. The silicon wafer is coated with SU-8 semiconductor ultraviolet photoresist. The SU-8 photoresist is spin-coated on the first substrate silicon wafer at a rotating speed of 1200 r/min, where the SU-8 photoresist spin-coated on the substrate has a thickness controlled at 180 microns. The first substrate silicon wafer is heated for 100 s at 100° C. by a uniform heating plate, fully dried and then transferred onto a lithography machine. An electrolytic tank mask is loaded onto the lithography machine for exposure, where the exposure is performed with an ultraviolet radiation dose of 200 mJ/cm² for 6-12 seconds.

1.3. Afterwards, SU-8 developing solution is used for sufficient development until a corrosion electrolytic tank pattern is clearly and completely presented.

1.4. Afterwards, the silicon wafer is etched by a femtosecond laser etching method to remove an exposed substrate region. The exposed substrate region is etched downwards to form a electrolytic bath for containing corrosive electrolyte, where the electrolytic bath serves as electrolytic tank for the corrosion electrochemical three-electrode reaction. The etching is performed at an etching rate of approximately 8 μm/min, and a total etching depth is 200 μm.

1.5. Step 1.1 is repeated to remove residual photoresist on the silicon wafer, and then the silicon wafer is cleaned with deionized water and dried for later use.

1.6. Steps 1.2 to 1.4 are repeated, with a difference that the mask used in this step is a working electrode mask. After exposure and development, a pattern of a working electrode region is dissolved to form a working electrode pattern in the electrolytic tank.

1.7. A working electrode required for material corrosion electrochemical measurement is formed by using a magnetron sputtering method. In this embodiment, the working electrode employs metal copper as a target material for magnetron sputtering, which also serves as an anode for this material corrosion electrochemical measurement, where a sputtering thickness is about 20 μm.

1.8. Step 1.1 is repeated to remove residual photoresist and the magnetron-sputtered working electrode material from the first substrate silicon wafer, and then the first substrate silicon wafer is cleaned with deionized water and dried for later use.

1.9. Steps 1.2 to 1.4 are repeated, with a difference that a mask used in this step is an auxiliary electrode mask. After exposure and development, a pattern of an auxiliary electrode region is dissolved to form an auxiliary electrode pattern in the electrolytic tank.

1.10. An auxiliary electrode required for material corrosion electrochemical measurement is formed by using the magnetron sputtering method. In this embodiment, a Pt target material is used, and a sputtering thickness is about 20 μm.

1.11. Step 1.1 is repeated to remove residual photoresist on the silicon wafer and the magnetron-sputtered auxiliary electrode material on the photoresist, and then the silicon wafer is cleaned with deionized water and dried for later use. As such, the electrolytic tank, the working electrode and the auxiliary electrode on the first substrate have been successfully prepared.

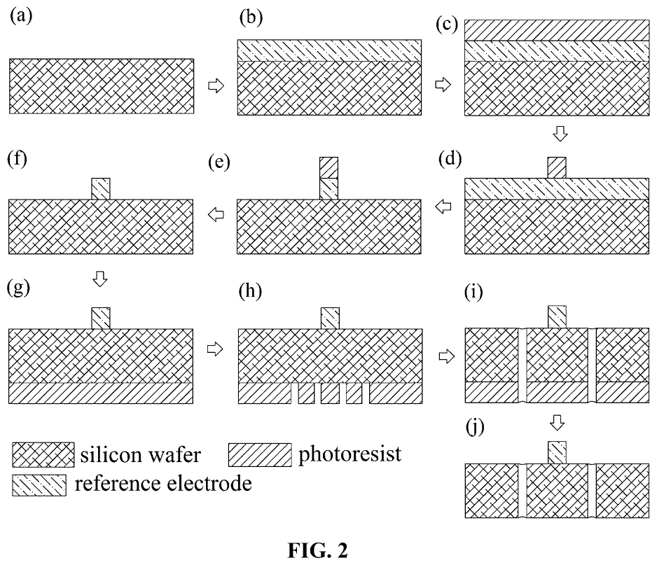

(2) As shown in FIG. 2, a preparation process of a reference electrode is specifically as follows.

2.1. A silicon wafer with a diameter of 100 mm and a thickness of 525 μm is used as a second substrate silicon wafer. A surface of the second substrate silicon wafer is cleaned with deionized water firstly. Afterwards, a cleaning solution composed of 25% hydrogen peroxide, 25% ammonia water and pure water in a volume ratio of 1:1:20 is used to clean the silicon wafer, where the cleaning lasts for about 260 s. Then, a cleaning solution composed of 30% hydrochloric acid, 25% hydrogen peroxide and pure water in a volume ratio of 1:1:20 is used to continually clean the silicon wafer for 250 s. Afterwards, the silicon wafer is washed with a large amount of deionized water, and dried by high-speed spin-drying equipment, where the spin-drying process lasts for 290 s.

2.2. A reference electrode required for material corrosion electrochemical measurement is prepared by using the magnetron sputtering method. In this embodiment, an Ag reference electrode is employed.

2.3. The silicon wafer is coated with SU-8 semiconductor ultraviolet photoresist, and the SU-8 photoresist is spin-coated on the second substrate silicon wafer at a rotating speed of 1200 r/min, where the SU-8 photoresist spin-coated on the substrate has a thickness controlled at 180 microns. The silicon wafer is heated for 100 s at 100° C. by a uniform heating plate, fully dried and then transferred to a lithography machine. A reference electrode mask is loaded onto the lithography machine for exposure, where the exposure is performed with an ultraviolet radiation dose of 200 mJ/cm² for 10 seconds.

2.4. Afterwards, SU-8 developing solution is used for sufficient development until a reference electrode pattern is clearly and completely presented.

2.5. Afterwards, the silicon wafer is etched by a deep silicon etching method to remove an exposed substrate region. The exposed substrate region is etched downward to form a groove which serves as a reference electrode for three-electrode reaction. The etching is performed at an etching rate of approximately 8 μm/min, and a total etching depth is 200 μm.

2.6. Step 1.1 is repeated to remove residual photoresist on the silicon wafer, and then the silicon wafer is cleaned with deionized water and dried for later use. As such, the Ag reference electrode is prepared.

2.7. Semiconductor photoresist is coated on one side, away from the reference electrode, of the second substrate silicon wafer, and the second substrate silicon wafer is subjected to soft baking. The silicon wafer is coated with SU-8 semiconductor ultraviolet photoresist. The SU-8 photoresist is spin-coated on a substrate at a rotating speed of 1200 r/min, where the SU-8 photoresist spin-coated on the substrate has a thickness controlled at 180 microns. The silicon wafer is heated for 100 s at 100° C. by a uniform heating plate, fully dried and then transferred onto a lithography machine. A through hole mask is loaded onto the lithography machine for exposure, where the exposure is performed with an ultraviolet radiation dose of 200 mJ/cm² for 10 seconds.

2.8. Afterwards, SU-8 developing solution is used for sufficient development until a through hole pattern is clearly and completely presented.

2.9. The silicon wafer is etched by using the deep silicon etching method to remove an exposed substrate region. The exposed substrate region is etched downwards to form a through hole.

2.10. Step 1.1 is repeated to remove residual photoresist on the silicon wafer, and then the silicon wafer is cleaned with deionized water and dried for later use. As such, the through hole is obtained.

(3) Silicon-silicon bonding

3.1. The first substrate silicon wafer with the working electrode, the auxiliary electrode and the electrolytic tank, and the second substrate silicon wafer with the reference electrode are subjected to silicon-silicon bonding. Prior to bonding, the first substrate silicon wafer and the second substrate silicon wafer are subjected to surface cleaning by employing an RCA (Radio Corporation of America) process to improve electrostatic tension on the surface of each silicon wafer. An A-component solution in the RCA process is prepared, which is a mixed solution of ammonia, hydrogen peroxide and water (ammonia:hydrogen peroxide:water=1:1:6) and is heated to 80° C. The substrate silicon wafer is soaked in the A component solution for 15 minutes and then taken out and washed with deionized water. A B-component solution in the RCA process is prepared, which is a mixed solution of hydrochloric acid, hydrogen peroxide and water (hydrochloric acid:hydrogen peroxide:water=1:1:5), the substrate silicon wafer is soaked in the B component solution for 15 minutes and then taken out and washed with deionized water. Afterwards, the two cleaned substrate silicon wafers are rinsed in a 2% diluted HF solution for 30 seconds to completely remove native oxide layers thereon, and then are washed with deionized water and spin-dried. At a room temperature, the two substrate silicon wafers are completely attached together to ensure that an attaching surface is smooth and free of impurities.

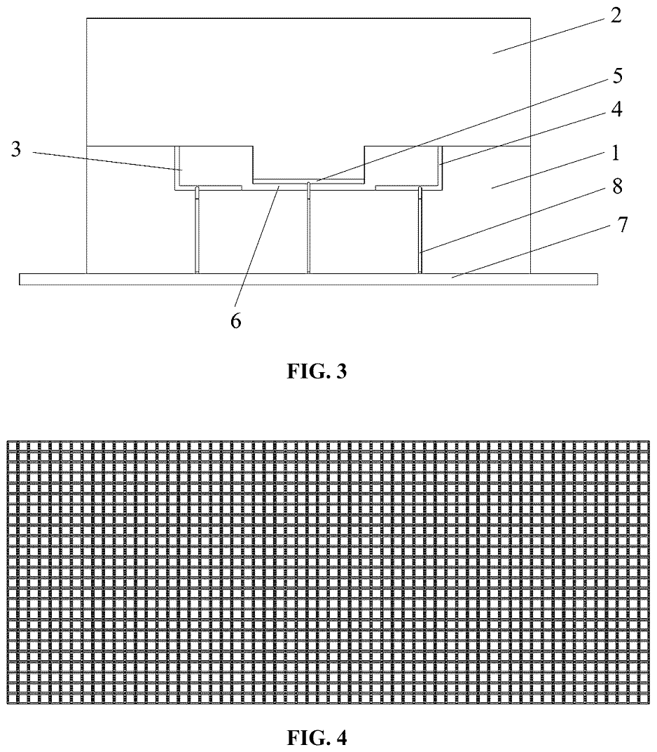

3.2. As shown in FIG. 3, the first substrate silicon wafer and the second substrate silicon wafer subjected to silicon-silicon bonding are subjected to high-temperature annealing treatment at 250° C. to enable physical-chemical reaction on a silicon-silicon bonding interface to form a chemical covalent bond connection and to enhance bonding strength, so that the first substrate and the second substrate are integrated together, where the unbonded rate is less than 0.5%, and the bonding strength is greater than 15 MPa.

The obtained corrosion electrochemical sensor includes a working electrode-auxiliary electrode module and a reference electrode module.

The working electrode-auxiliary electrode module includes a first silicon substrate 1 provided with a recess portion. The reference electrode module includes a second silicon substrate 2, and the first silicon substrate 1 is fixedly connected to the second silicon substrate 2. The working electrode 3 is disposed on a left side of an inner wall and on a left side of the bottom wall of the recess portion, and the working electrode 3 is L-shaped in a whole. The auxiliary electrode 4 is disposed on a right side of the inner wall and on a right side of the bottom of the recess portion, and the auxiliary electrode 4 is L-shaped in a whole. The working electrode 3, the auxiliary electrode 4 and the recess portion form an accommodation space. The reference electrode 5 is disposed on one side of the second silicon substrate 2 and forms a protruding portion, and the reference electrode 5 is arranged in the accommodation space and is not connected to the working electrode 3, the auxiliary electrode 4 and the reference electrode 5. The recess portion serves as an electrolytic tank 6.

This embodiment further provides material corrosion electrochemical measurement equipment, including the MEMS-based material corrosion electrochemical measurement sensor described above and a base lead frame 7 (as shown in FIG. 4). The base lead frame 7 is further provided with bonding wires 8 which are connected to the working electrode 3, the auxiliary electrode 4 and the reference electrode 5, respectively.

The preparation method for the material corrosion electrochemical measurement equipment includes lead bonding.

4.1. A copper-nickel alloy base lead frame 7 suitable for MEMS-based corrosion electrochemical measurement is designed, and the bonded silicon wafers are cut and placed on the frame. To ensure the bonding quality between the frame and the working electrode 3, the auxiliary electrode 4 and the reference electrode 5 on the bonded silicon wafers, prior to bonding, plasma cleaning equipment is used for cleaning the silicon wafers and the frame, which is performed at a 200 W power under the argon flow rate of 10 ml/min for 10 s.

4.2. A copper wire bonding process is employed for precisely welding the working electrode 3, the auxiliary electrode 4 and the reference electrode 5 onto the copper-nickel alloy base lead frame 7 via the bonding pad 9, thereby achieving electrical interconnection between the MEMS chips and the substrate, and information communication between the chips.

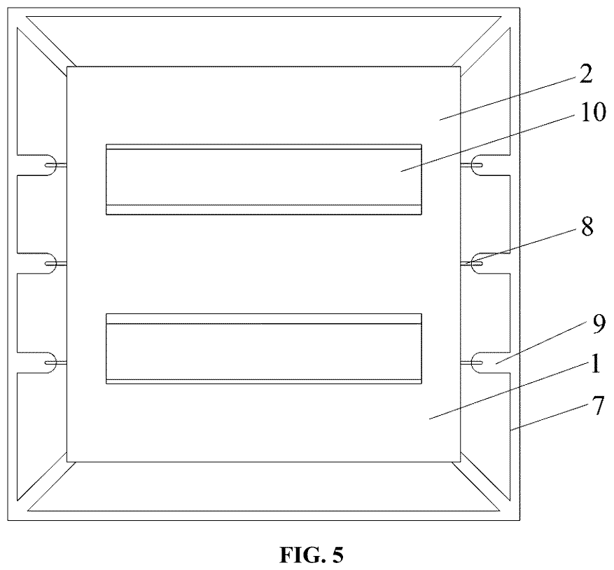

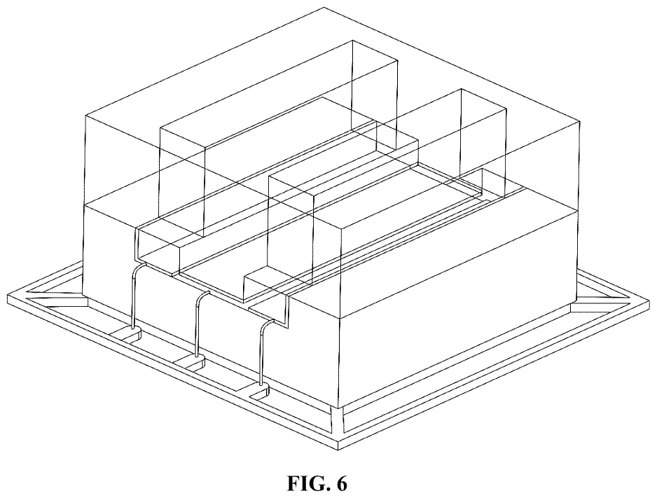

As shown in FIG. 5 and FIG. 6, the second silicon substrate is provided with two through holes 10 in a thickness direction for flowing a fluid medium such as electrolyte into the electrolytic tank 6.

5. Sensor test

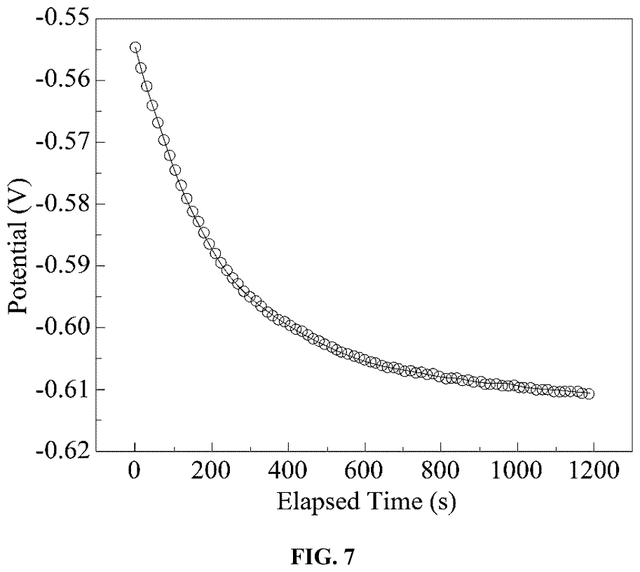

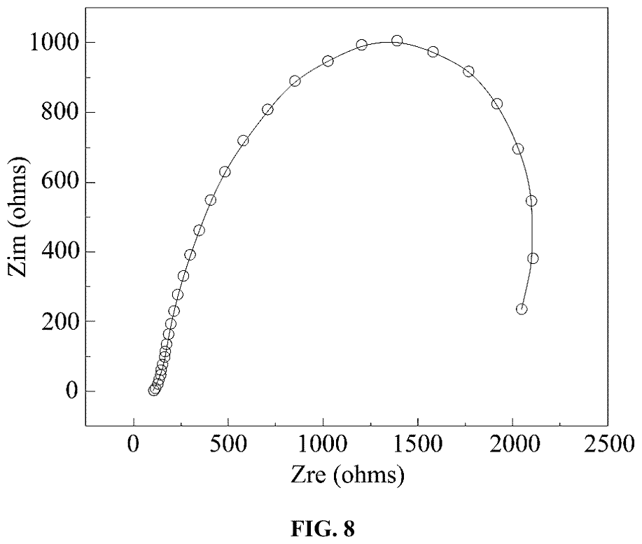

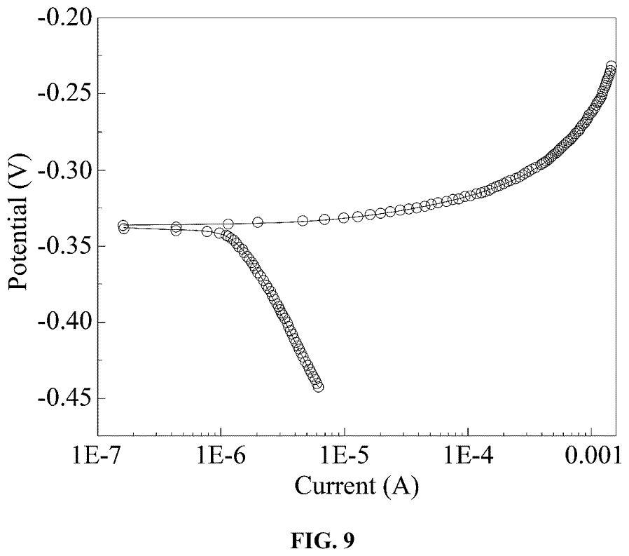

5.1. The sensor in this embodiment is placed in an alternating temperature and humidity test chamber for electrochemical test, including electrochemical open-circuit potential, electrochemical alternating current impedance and weak polarization tests. During the test, the humidity is controlled at 100% and the temperature is controlled at 25° C. Before the test, the system is stably placed for 2 hours, and the open-circuit potential test lasts for 1200 s, with the results shown in FIG. 7. A scanning frequency of AC impedance is 0.01 Hz-100 kHz, and an applied interference voltage is 10 mV, with a result of an AC impedance test shown in FIG. 8. The polarization potential test is performed with a scanning within +10 mV relative to reference potential at a scan frequency of 0.1667 Hz, with a result shown in FIG. 9.

In this embodiment, the assembled corrosion electrochemical three-electrode system should be arranged in the sequence of the working electrode, the reference electrode and the auxiliary electrode, in which a spacing between the working electrode and the reference electrode is 2000 μm. An excessively close distance between the working electrode and the reference electrode may cause charge shielding, affecting the corrosion electrochemical reaction, while an excessively long distance between the working electrode and the reference electrode may cause a substantial ohmic drop, which directly affects the accuracy of electrochemical measurements. In addition, the working electrode and the auxiliary electrode are in the same shape and are arranged discharged in opposite directions with a spacing of 4000 μm, thereby forming a good charge loop and fully ensuring the accuracy of corrosion electrochemical measurement. In addition, it is provided comparative examples to measure AC impedance, fully considering the influence of positions of electrodes and a spacing between electrodes on corrosion electrochemical measurement during corrosion electrochemical measurement.

### Comparative Example 1

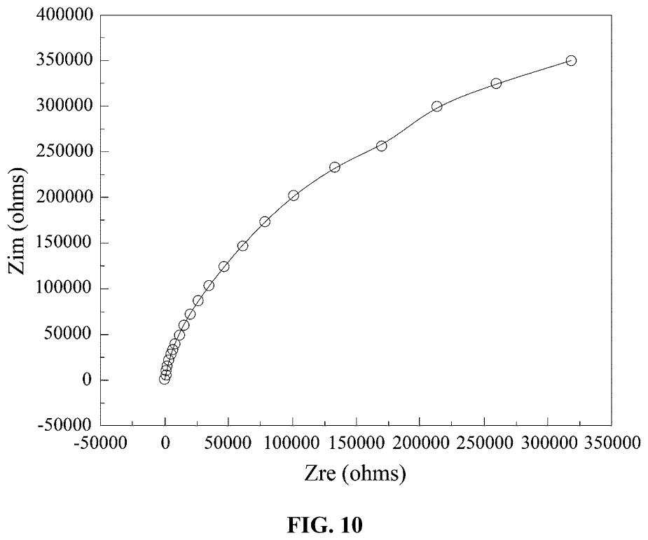

A difference from Embodiment is that a spacing between the working electrode and the reference electrode is controlled at 500 μm, a spacing between the working electrode and the auxiliary electrode is still kept at 4000 μm, and the electrochemical impedance is measured based on the corrosion electrochemical measurement method in Embodiment, with a result shown in FIG. 10. FIG. 10 shows that the measured electrochemical impedance is significantly increased primarily due to the excessive small spacing between the working electrode and the reference electrode. This excessive small spacing creates an electrochemical shielding effect, and hinders solution infiltration under electrostatic tension.

### Comparative Example 2

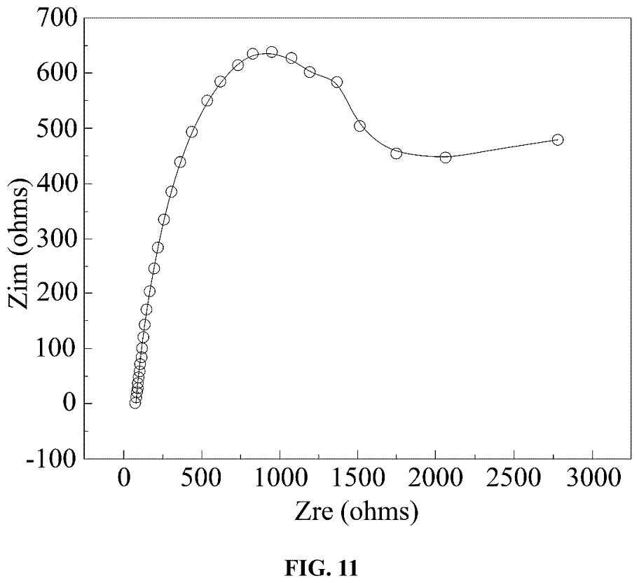

A difference from Embodiment is that an arrangement sequence of the working electrode, the reference electrode and the auxiliary electrode is controlled as follows: the working electrode, the auxiliary electrode and the reference electrode. The distance between the working electrode and the reference electrode is 4000 μm, the distance between the working electrode and the auxiliary electrode is 2000 μm, and the electrochemical impedance is measured based on the corrosion electrochemical measurement method in Embodiment, with a result shown in FIG. 11. FIG. 11 shows that an impedance value corresponding to a low frequency part of the measured electrochemical impedance is significantly increased, indicating that there is a large ohmic drop in the system. The ohmic drop results from the excessive large distance between the working electrode and the reference electrode. When a perturbation potential is applied to the working electrode for impedance measurement, the actual potential applied is greatly diminished because of the ohmic drop. The MEMS-based material corrosion electrochemical measurement sensor provided by the present disclosure has the characteristics of small volume and low cost, is mature in preparation method, convenient for large-scale integration and batch fabrication, satisfying the requirements for online corrosion electrochemical monitoring of components with various specifications and materials.

Finally, it should be noted that the foregoing embodiments are merely used to describe the technical solution of the present disclosure, rather than limitation. Although the present disclosure is described in detail with reference to the foregoing embodiments, a person of ordinary skill in the art should understand that: the technical solutions described in the foregoing embodiments may still be modified, or some technical features or all technical features thereof may be equivalently replaced. These modifications or replacements shall not cause the essential nature of the corresponding technical solution to deviate from the scope of the technical solutions of embodiments of the present disclosure.

What is claimed is:

1. A Micro-Electro-Mechanical System (MEMS)-based material corrosion electrochemical measurement sensor, comprising:
a working electrode-auxiliary electrode module, comprising a first silicon substrate, a working electrode and an auxiliary electrode, wherein the first silicon substrate is provided with a recess portion, the working electrode is disposed on one side of an inner wall of the recess portion and a bottom of the recess portion, the auxiliary electrode is disposed on an opposite other side of the inner wall of the recess portion and the bottom of the recess portion, and the working electrode, the auxiliary electrode and the recess portion form an accommodation space; and
a reference electrode module, comprising a second silicon substrate and a reference electrode, wherein the reference electrode is disposed on one side of the second silicon substrate and forms a protruding portion, and the second silicon substrate is provided with a through hole in a thickness direction thereof,
wherein the protruding portion is disposed within the accommodation space, the working electrode, the auxiliary electrode and the reference electrode are not connected with one another, and the first silicon substrate is fixedly connected to the second silicon substrate;
a spacing between the working electrode and the reference electrode is 1000 μm-2000 μm, and a spacing between the working electrode and the auxiliary electrode is 1000 μm-5000 μm;
a cross section of each of the working electrode and the auxiliary electrode is L-shaped; and
each of the working electrode, the auxiliary electrode and the reference electrode is made of a target metal material to be tested.

2. The MEMS-based material corrosion electrochemical measurement sensor according to claim 1, wherein a pair of the accommodation space and the protruding portion comprises a plurality of pairs of accommodation spaces and protruding portions.

3. A preparation method for the MEMS-based material corrosion electrochemical measurement sensor according to claim 1, comprising:
coating first semiconductor photoresist on one side of the first silicon substrate and carrying out first soft baking, carrying out exposure, development and dissolution by means of an electrolytic tank mask under corresponding ultraviolet light to form an exposed substrate region, and etching the exposed substrate region by ion etching to obtain the recess portion;
removing residual first semiconductor photoresist, coating second semiconductor photoresist on one side, with the recess portion, of the first silicon substrate and carrying out second soft baking, and carrying out exposure, development and dissolution by means of a working electrode mask under corresponding ultraviolet light to form a working electrode pattern, and forming a working electrode layer by disposing the target metal material to be tested on a position of the working electrode pattern by using a sputtering or electroplating method;
removing residual second semiconductor photoresist and a residual metal material to obtain the working electrode;
coating third semiconductor photoresist on one side, with the recess portion, of the first silicon substrate and carrying out third soft baking, and carrying out exposure, development and dissolution by means of an auxiliary electrode mask under corresponding ultraviolet light to form an auxiliary electrode pattern;
forming an auxiliary electrode layer by disposing the target metal material to be tested on a position of the auxiliary electrode pattern by using the sputtering or electroplating method;
removing residual third semiconductor photoresist and a residual metal material to obtain the auxiliary electrode, thereby obtaining the working electrode-auxiliary electrode module;
disposing a reference electrode layer on a surface of one side of the second silicon substrate by using the sputtering or electroplating method, then coating fourth semiconductor photoresist and carrying out fourth soft baking, and carrying out exposure, development and dissolution by means of the auxiliary electrode mask under corresponding ultraviolet light to form a reference electrode pattern, etching at a position of the reference electrode pattern by ion etching, and removing residual fourth semiconductor photoresist and a residual metal material to obtain the reference electrode;
coating fifth semiconductor photoresist on one side, away from the reference electrode, of the second silicon substrate and carrying out fifth soft baking, and carrying out exposure, development and dissolution by means of a through hole mask under corresponding ultraviolet light to form a through hole pattern, and etching at a position of the through hole pattern by the ion etching to obtain the through hole, thereby obtaining the reference electrode module; and
carrying out silicon-silicon bonding on the working electrode-auxiliary electrode module and the reference electrode module to obtain the MEMS-based material corrosion electrochemical measurement sensor.

4. The preparation method for the MEMS-based material corrosion electrochemical measurement sensor according to claim 3, wherein the first silicon substrate and the second silicon substrate are cleaned before use.

5. The preparation method for the MEMS-based material corrosion electrochemical measurement sensor according to claim 3, wherein temperatures for the first soft baking, the second soft baking, the third soft baking, the fourth soft baking and the fifth baking are independently 90° C.-110° C. respectively.

6. The preparation method for the MEMS-based material corrosion electrochemical measurement sensor according to claim 3, wherein prior to the silicon-silicon bonding, the first silicon substrate and the second silicon substrate are subjected to surface cleaning; and
the silicon-silicon bonding employs a heating-annealing treatment.

7. Material corrosion electrochemical measurement equipment, comprising the MEMS-based material corrosion electrochemical measurement sensor according to claim 1.

8. The material corrosion electrochemical measurement equipment according to claim 7, further comprising a base lead frame,
wherein the working electrode, the auxiliary electrode and the reference electrode are electrically connected to the base lead frame.

9. The preparation method for the MEMS-based material corrosion electrochemical measurement sensor according to claim 3, wherein a pair of the accommodation space and the protruding portion comprises a plurality of pairs of accommodation spaces and protruding portions.

10. The preparation method for the MEMS-based material corrosion electrochemical measurement sensor according to claim 4, wherein a pair of the accommodation space and the protruding portion comprises a plurality of pairs of accommodation spaces and protruding portions.

11. The preparation method for the MEMS-based material corrosion electrochemical measurement sensor according to claim 5, wherein a pair of the accommodation space and the protruding portion comprises a plurality of pairs of accommodation spaces and protruding portions.

12. The preparation method for the MEMS-based material corrosion electrochemical measurement sensor according to claim 6, wherein the first silicon substrate and the second silicon substrate are cleaned before use.

13. The preparation method for the MEMS-based material corrosion electrochemical measurement sensor according to claim 6, wherein temperatures for the first soft baking, the second soft baking, the third soft baking, the fourth soft baking and the fifth baking are independently 90° C.-110° C. respectively.

14. The preparation method for the MEMS-based material corrosion electrochemical measurement sensor according to claim 6, wherein a pair of the accommodation space and the protruding portion comprises a plurality of pairs of accommodation spaces and protruding portions.

15. The preparation method for the MEMS-based material corrosion electrochemical measurement sensor according to claim 12, wherein a pair of the accommodation space and the protruding portion comprises a plurality of pairs of accommodation spaces and protruding portions.

16. The preparation method for the MEMS-based material corrosion electrochemical measurement sensor according to claim 13, wherein a pair of the accommodation space and the protruding portion comprises a plurality of pairs of accommodation spaces and protruding portions.

17. The material corrosion electrochemical measurement equipment according to claim 7, wherein a pair of the accommodation space and the protruding portion comprises a plurality of pairs of accommodation spaces and protruding portions.

18. The material corrosion electrochemical measurement equipment according to claim 8, wherein a pair of the accommodation space and the protruding portion comprises a plurality of pairs of accommodation spaces and protruding portions.
